(19) United States
(12) Patent Application Publication
(10) Pub. No.: US 2025/0264897 A1
(43) Pub. Date: Aug. 21, 2025

(54) REGULATOR AND POWER DEVICE

(71) Applicant: Renesas Electronics Corporation, Tokyo (JP)

(72) Inventors: Kiyoshi MIYAZAKI, Tokyo (JP); Masayuki OTSUKA, Tokyo (JP)

(73) Assignee: Renesas Electronics Corporation, Tokyo (JP)

(21) Appl. No.: 19/051,342

(22) Filed: Feb. 12, 2025

(30) Foreign Application Priority Data
Feb. 16, 2024 (JP) 2024-021989

(51) Int. Cl. G05F 1/573; G05F 1/575; H03K 17/082

(52) U.S. Cl. CPC G05F 1/573; G05F 1/575; H03K 17/0822

(57) ABSTRACT

A regulator includes a reference potential generation circuit that generates a reference potential serving as a reference for an intermediate potential and an intermediate potential lower than the intermediate potential, a differential amplifier to which the intermediate potential is supplied as a low potential side power supply and which amplifies a difference voltage between a feedback potential corresponding to the intermediate potential and the reference potential, and a transistor having a gate to which the amplified difference voltage is input, a drain connected to a ground potential via a constant current source or a resistor, and a source that generates the intermediate potential.

### CROSS-REFERENCE TO RELATED APPLICATION

This application claims priority under 35 U.S.C. § 119 to Japanese Patent Application No. 2024-021989 filed on Feb. 16, 2024. The disclosure of Japanese Patent Application No. 2024-021989, including the specification, drawings and abstract, is incorporated herein by reference in its entirety.

### BACKGROUND

The present invention relates to a regulator and a power device.

There are disclosed techniques listed below.

[Patent Document 1] Japanese Unexamined Patent Application Publication No. 2020-014356

Patent Document 1 discloses a technique for generating an intermediate potential using a Zener diode.

### SUMMARY

Patent Document 1 discloses that the current flowing through a Zener diode is set according to the maximum current of a circuit to which an intermediate potential is supplied, such as an internal circuit of a power device. Therefore, there is a problem in that a large current is required to generate the intermediate potential.

The present disclosure has been made to solve such a problem and aims to implement a regulator and a power device that can be controlled with a small current.

Other issues and novel features will become apparent from the description of the present specification and the accompanying drawings.

According to one embodiment, a regulator includes a reference potential generation circuit that generates a reference potential serving as a reference for a first intermediate potential and a second intermediate potential lower than the first intermediate potential, a differential amplifier to which the second intermediate potential is supplied as a low potential side power supply and which amplifies a difference voltage between a feedback potential corresponding to the first intermediate potential and the reference potential, and a first transistor having a gate to which the amplified difference voltage is input, a drain connected to a ground potential via a constant current source or a resistor, and a source that generates the first intermediate potential.

According to one embodiment, a power device includes a reference potential generation circuit that generates a reference potential serving as a reference for a first intermediate potential and a second intermediate potential lower than the first intermediate potential, a differential amplifier to which the second intermediate potential is supplied as a low potential side power supply and which amplifies a difference voltage between a feedback potential corresponding to the first intermediate potential and the reference potential, a first transistor having a gate to which the amplified difference voltage is input, a drain connected to a ground potential via a constant current source or a resistor, and a source that generates the first intermediate potential, and a control circuit to which the first intermediate potential is supplied as a low potential side power supply and that controls a power transistor.

According to the embodiments, it is possible to provide a regulator and a power device that can be controlled with a small current.

### BRIEF DESCRIPTION OF THE DRAWINGS

FIG. 1 is a circuit diagram illustrating a configuration of a regulator according to a first embodiment.

FIG. 2 is a circuit diagram illustrating a configuration of a regulator according to a first modification of the first embodiment.

FIG. 3 is a circuit diagram illustrating a configuration of a regulator according to a second modification of the first embodiment.

FIG. 4 is a circuit diagram illustrating a configuration of a regulator according to a second embodiment.

FIG. 5 is a schematic circuit diagram illustrating a configuration of a power device according to a third embodiment.

### DETAILED DESCRIPTION

For clarity of description, the following description and drawings have been omitted and simplified as appropriate. In each drawing, the same elements are given the same reference numerals, and duplicated descriptions are omitted as necessary.

### First Embodiment

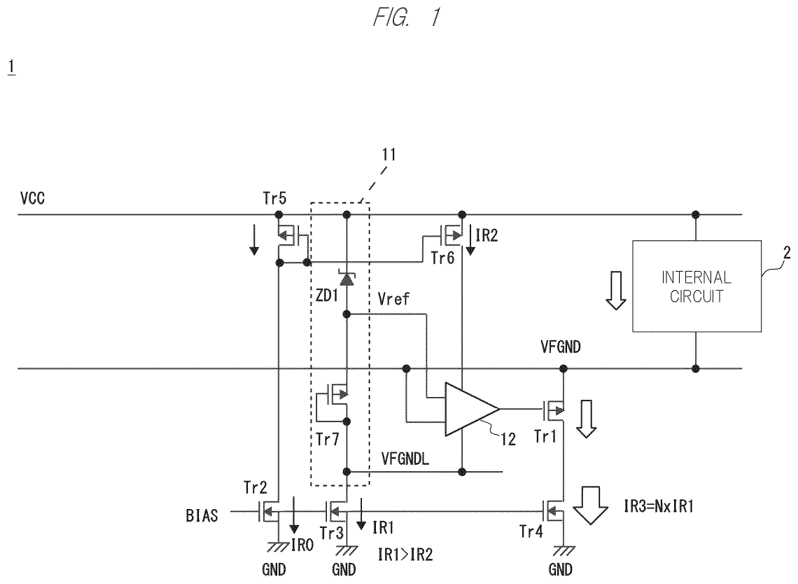

FIG. 1 is a circuit diagram illustrating a configuration of a regulator 1 according to a first embodiment. The regulator 1 uses a power supply voltage VCC as the input voltage and generates an intermediate potential VFGND as the output voltage. The intermediate potential VFGND is also referred to as a first intermediate potential. The intermediate potential VFGND is supplied to an internal circuit 2 as a low potential side power supply voltage. Although, the internal circuit 2 specifically refers to an internal circuit of an intelligent power device (IPD), such as a control circuit, the internal circuit 2 may be any arbitrary circuit. The intermediate potential VFGND is preferably a voltage that is about 5 to 8V lower than the power supply voltage VCC so that the internal circuit 2 can be formed with low-voltage elements.

The regulator 1 includes a reference potential generation circuit 11, differential amplifier 12, and a p-channel metal oxide semiconductor (MOS) transistor Tr1. The reference potential generation circuit 11 generates a reference potential Vref and an intermediate potential VFGNDL. The reference potential Vref and the intermediate potential VFGNDL are also referred to as a first reference potential and a second reference potential, respectively. The intermediate potential VFGNDL is lower than the intermediate potential VFGND. The intermediate potential VFGNDL is also referred to as a second intermediate potential. The intermediate potentials VFGND and VFGNDL are potentials between the power supply potential VCC and the ground potential GND. Note that, for the p-channel MOS transistor Tr1, a metal oxide semiconductor field-effect transistor (MOSFET) may also be used. To drive the p-channel MOS transistor Tr1, the intermediate potential VFGNDL is preferably a voltage that is about 1V lower than the intermediate potential VFGND.

The regulator 1 further includes n-channel MOS transistors Tr2 to Tr4 and p-channel MOS transistors Tr5 to Tr6. The sources of the MOS transistor Tr2, Tr3, and Tr4 are connected to the ground potential GND. A bias voltage BIAS is supplied to the gates of the MOS transistors Tr2, Tr3, and Tr4. The MOS transistors Tr2, Tr3, and Tr4 each function as a constant current source. The MOS transistor Tr5 is connected in series with the MOS transistor Tr2, and the MOS transistor Tr4 is connected in series with the MOS transistor Tr1. The MOS transistor Tr6 is provided in the path supplying the power supply potential VCC to the differential amplifier 12, and functions as a constant current source to ensure stable operation of the differential amplifier 12. The gates of the MOS transistors Tr5 and Tr6 are connected to the drain of the MOS transistor Tr5.

The reference potential generation circuit 11 includes a Zener diode ZD1 and a p-channel MOS transistor Tr7. The Zener diode ZD1 is also referred to as a second Zener diode. The Zener diode ZDI and the MOS transistor Tr7 are connected in series and are provided in the path between the power supply potential VCC and the MOS transistor Tr3. The cathode of the Zener diode ZD1 is connected to the power supply potential VCC. The gate and the drain of the MOS transistor Tr7 are connected to each other, and the MOS transistor Tr7 functions as a diode. The anode of the diode is connected to the anode of the Zener diode ZD1.

The reference potential Vref, which serves as the reference for the intermediate potential VFGND, is generated at the anode of the Zener diode ZD1. When a Zener voltage of the Zener diode ZDI is denoted as Vz, then the reference potential Vref is given by VCC−Vz. The intermediate potential VFGNDL is generated at the cathode of the diode formed by the MOS transistor Tr7.

The intermediate potential VFGNDL is supplied to the differential amplifier 12 as the low potential side power supply voltage. The reference potential Vref is input to a first input terminal of the differential amplifier 12. A potential corresponding to the intermediate potential VFGND is provided as a feedback potential to a second input terminal of the differential amplifier 12. Specifically, the source voltage of the MOS transistor Tr1 is provided as the feedback potential to the second input terminal of the differential amplifier 12. The differential amplifier 12 amplifies the difference voltage between the reference potential Vref and the feedback potential, and outputs the amplified difference voltage.

The gate of the MOS transistor Tr1 is connected to an output of the differential amplifier 12. That is, the amplified difference voltage described above is input to the gate of the MOS transistor Tr1. The drain of the MOS transistor Tr1 is connected to the ground potential GND via the MOS transistor Tr4 that forms a constant current source. Also, the drain of the MOS transistor Tr1 may be connected to the ground potential GND via a resistor instead of the MOS transistor Tr4. The resistor may be a resistor used to limit the current in the internal circuit 2. The source of the MOS transistor Tr1 is an output of the regulator 1. That is, the source voltage of the MOS transistor Tr1 is the output voltage of the regulator 1, which is the intermediate potential VFGND. The MOS transistors Tr1 and Tr4 form a source follower circuit.

The current flowing through the MOS transistors Tr2 and Tr5 is IR0, the current flowing through the MOS transistor Tr3 is IR1, the current flowing through the MOS transistor Tr6 is IR2, and the current flowing through the MOS transistor Tr4 is IR3. The MOS transistor Tr6 is configured so that the current IR2 is a copy of the current IR0 at a predetermined mirror ratio. The current IR2 flows to the differential amplifier 12. The MOS transistor Tr3 is configured so that the current IR1 is larger than the current IR2. The difference between the current IR1 and the current IR2 flows through the reference potential generation circuit 11. The current IR3 is N times the current IR1, and is set based on the maximum current flowing through the internal circuit 2. In idle mode, the currents IR0 and IR1 may be controlled to be small.

The operation of the regulator 1 according to the first embodiment will be described. As described above, the regulator 1 receives the power supply voltage VCC as an input and outputs the intermediate potential VFGND. The intermediate potential VFGND is the source voltage of the MOS transistor Tr1. The MOS transistor Tr1 is controlled by the output of the differential amplifier 12.

The differential amplifier 12 controls the MOS transistor Tr1 based on the difference voltage between the reference voltage Vref and the source voltage of the MOS transistor Tr1, which serves as the feedback potential. That is, the differential amplifier 12 controls the MOS transistor Tr1 in response to the potential fluctuation of the intermediate potential VFGND. For example, when the potential of the intermediate potential VFGND falls below the reference potential Vref due to a load fluctuation in the internal circuit 2, the differential amplifier 12 controls so as to raise the voltage of the gate of the MOS transistor Tr1. Since the MOS transistor Tr1 functions as a source follower, the source voltage rises following the gate voltage of the MOS transistor Tr1. This causes the intermediate potential VFGND to rise. On the other hand, when the potential of the intermediate potential VFGND becomes higher than the reference potential Vref due to a load fluctuation of the internal circuit 2, the differential amplifier 12 controls the gate voltage of the MOS transistor Tr1 to fall. As a result, the voltage at the source of the MOS transistor Tr1 falls following the gate voltage of the MOS transistor Tr1. Through such operation, the intermediate potential VFGND is stabilized at a value equal to the reference voltage Vref.

In the regulator 1 according to the first embodiment, the intermediate potential VFGNDL is supplied to the differential amplifier 12 as the low potential side power supply. Since the differential amplifier 12 only needs to control the MOS transistor Tr1, the intermediate potential VFGNDL as the low potential side power supply voltage can be about 1V lower than the intermediate potential VFGND (VCC−VFGNDL=6 to 9V). As a result, the differential amplifier 12 can be formed with low-voltage elements and low-voltage circuits, allowing for a reduction in the current flowing through the differential amplifier 12. Also, the currents IR1 and IR2 for the reference potential generation circuit 11 and the differential amplifier 12 can be set regardless of the current supplied to the internal circuit 2. Thus, the current flowing through the reference potential generation circuit 11 can also be reduced.

Therefore, the regulator 1 according to the first embodiment can be controlled with a small current. Further, since the differential amplifier 12 can be formed with low-voltage elements, the circuit scale is small and control is easy.

Since the output of the differential amplifier 12 is always at about the intermediate potential VFGND−Vtp, the response speed of the MOS transistor Tr1 is fast and the risk of oscillation is low. Vtp represents the threshold voltage of the p-channel MOS transistor Tr1.

### First Modification of First Embodiment

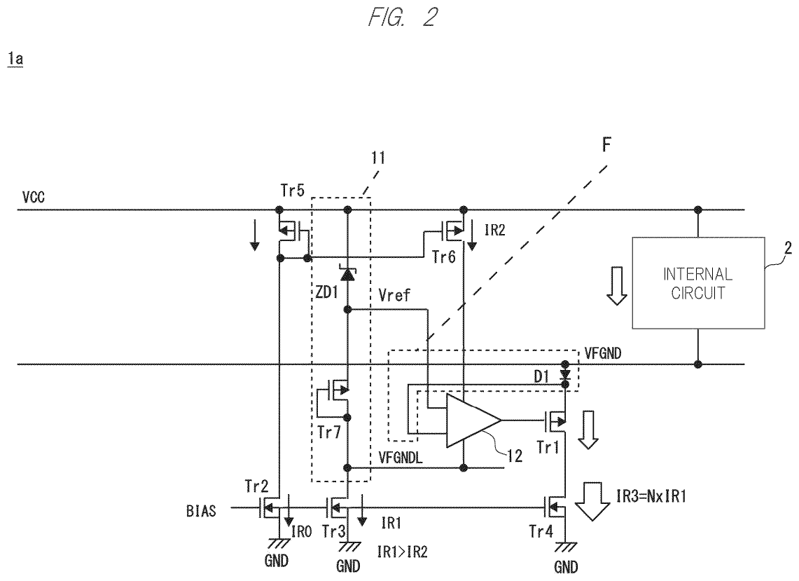

FIG. 2 is a circuit diagram illustrating a configuration of a regulator 1a according to a first modification. Comparing FIG. 1 with FIG. 2, the regulator 1a according to the first modification further includes a feedback circuit F. The feedback circuit F includes a diode D1. The cathode of the diode D1 is connected to the source of the MOS transistor Tr1. The anode of the diode D1 serves as the output of the regulator 1a.

When the Zener voltage of the Zener diode ZDI is Vz and the forward voltage of the diode D1 is VF, the regulator 1a controls the MOS transistor Tr1 to satisfy VFGND−VF=VCC−Vz. Therefore, the intermediate potential VFGND is stabilized at (VCC−Vz)+VF.

The regulator 1a according to the first modification generates an intermediate potential VFGND different from the reference voltage Vref of the differential amplifier 12 by using the feedback circuit F.

### Second Modification of First Embodiment

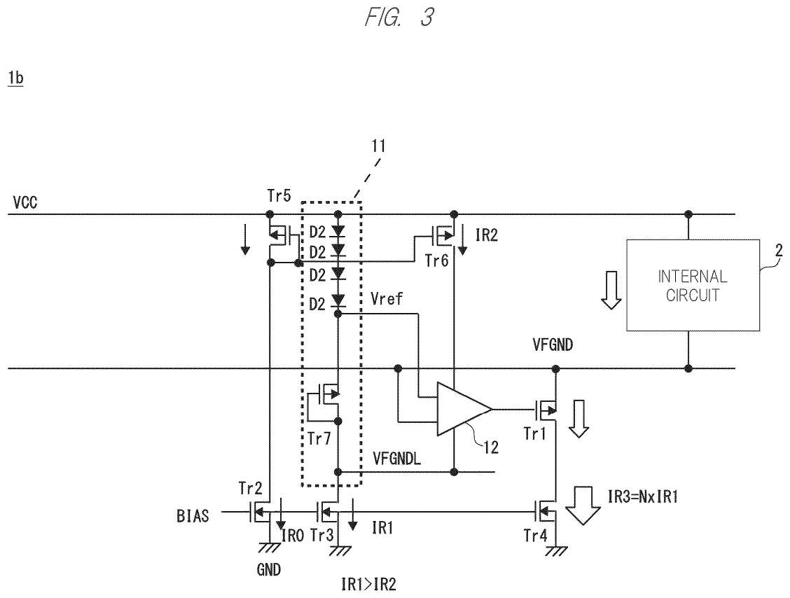

FIG. 3 is a circuit diagram illustrating a configuration of a regulator 1b according to a second modification. Comparing FIG. 1 with FIG. 3, the Zener diode ZD1 forming the reference potential generation circuit 11 is replaced with a plurality of diodes D2 connected in series with each other. The diode may be a MOS transistor having the gate and the drain connected with each other. Also, instead of the diode, a circuit element such as a resistor may be used.

As in the reference potential generation circuit 11 according to the second modification, the reference potential may be generated using a diode or a resistor, rather than being limited to a Zener diode.

### Second Embodiment

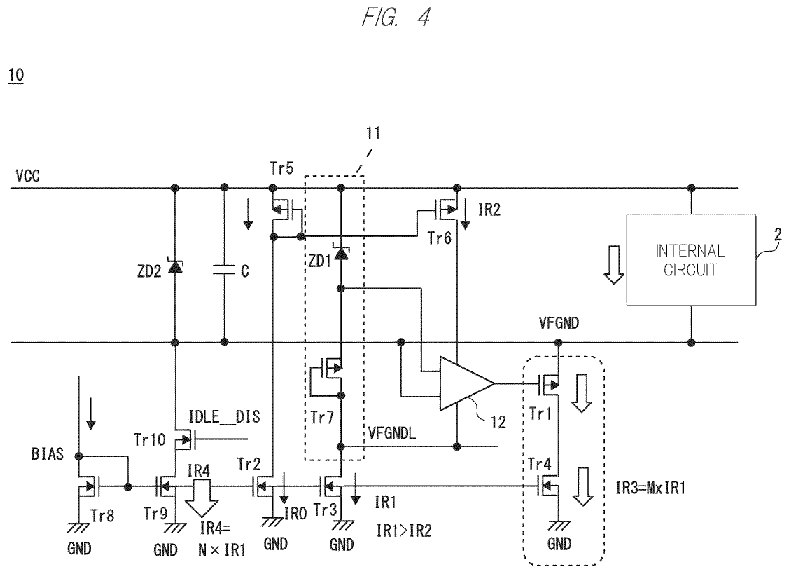

FIG. 4 is a circuit diagram illustrating a configuration of a regulator 10 according to a second embodiment.

Comparing FIG. 1 with FIG. 4, the regulator 10 further includes a Zener diode ZD2, a capacitor C, and n-channel MOS transistors Tr8 to Tr10.

The cathode of the Zener diode ZD2 is connected to the power supply potential VCC, and the anode of the Zener diode ZD2 is connected to the output of the regulator 10. The Zener diode ZD2 is also referred to as a first Zener diode.

The capacitor C is connected in parallel to the Zener diode ZD2.

The sources of the MOS transistors Tr8 and Tr9 are connected to the ground potential GND. The gates of the MOS transistors Tr8 and Tr9 are connected to the drain of the MOS transistor Tr8. The MOS transistor Tr9 copies the current flowing through the MOS transistor Tr8 and supplies the current to the Zener diode ZD2.

The MOS transistor Tr10 is provided in the path between the Zener diode ZD2 and the MOS transistor Tr9. The MOS transistor Tr10 is also referred to as a second transistor. A control signal IDLE_DIS is input to the gate of the MOS transistor Tr10. The control signal IDLE_DIS is a signal for instructing whether the internal circuit 2 is to be in idle mode or normal mode. In the second embodiment, the control signal IDLE_DIS is at an H level when idle mode of the internal circuit 2 is disabled, that is, when the internal circuit 2 is in normal mode. Accordingly, the MOS transistor Tr10 functions as a switch that uses the control signal IDLE_DIS to toggle the connection state between the Zener diode ZD2 and the MOS transistor Tr9.

The current flowing through the MOS transistor Tr9 is represented as IR4. The MOS transistor Tr9 is configured such that the current IR4 is larger than the maximum current of the internal circuit 2 in normal mode. The current IR4 is set to N times (N is an integer equal to or larger than 1) the current IR1 flowing through the MOS transistor Tr3. Also, the MOS transistor Tr4 is configured such that the current IR3 flowing through the MOS transistor Tr4 is larger than the maximum current of the internal circuit 2 in idle mode. The current IR3 is set to M times (M is an integer equal to or greater than 1) the current IR1. The current IR4 is greater than the current IR3. That is, N is greater than M.

The source voltage of the MOS transistor Tr1 is the intermediate potential VFGND supplied to the internal circuit 2, similarly to the first embodiment. When the internal circuit 2 is in idle mode, the control signal IDLE_ DIS indicates an L level, so that the MOS transistor Tr10 is controlled to be in an Off state. Therefore, when the internal circuit 2 is in idle mode, the current flowing through the internal circuit 2 flows through the path provided with the MOS transistors

Tr1 and Tr4. The internal circuit 2 is supplied with the intermediate potential VFGND generated by the MOS transistor Tr1.

When the internal circuit 2 is in normal mode, the control signal IDLE_DIS indicates an H level, so that the MOS transistor Tr10 is controlled to be in an ON state. Therefore, when the internal circuit 2 is in normal mode, the current flowing through the internal circuit 2 mainly flows through the path in which the MOS transistor Tr9 is provided. Then, the difference between the current IR4 and the current flowing through the internal circuit 2 flows through the Zener diode ZD2, and the intermediate potential VFGND is generated at the anode of the Zener diode ZD2. The internal circuit 2 is supplied with the intermediate potential VFGND generated by the Zener diode ZD2. When the internal circuit 2 is in normal mode, in order to suppress fluctuations in the intermediate potential VFGND, the current IR4 flowing through the MOS transistor Tr9 is made larger than the current flowing through the internal circuit 2 in normal mode.

The differential amplifier 12 may include a function for adjusting the offset. For example, the offset of the differential amplifier 12 may be adjusted so that the intermediate potential VFGND generated by the MOS transistor Tr1 is higher than the intermediate potential VFGND generated by the Zener diode ZD2.

Further, the differential amplifier 12 includes a function for adjusting the offset, so that the influence of the characteristic variations of the Zener diodes ZD1 and ZD2 can be reduced. For example, consider a case in which the characteristics of the Zener diode ZDI and the Zener diode ZD2 vary in the second embodiment. The output of the regulator 10, that is, the source voltage of the MOS transistor Tr1, is controlled by the differential amplifier 12 so as to become the voltage of the Zener diode ZD1. Due to the difference between the voltage generated by the Zener diode ZD2 and the voltage by the Zener diode ZD1, unnecessary current may flow. However, by adjusting the offset of the differential amplifier 12, it is possible to reduce such unnecessary current.

When the internal circuit 2 is in normal mode, it is necessary to make the current IR4 flowing through the MOS transistor Tr9 larger than the current flowing through the internal circuit 2 during normal mode in order to stably supply the intermediate potential VFGND. On the other hand, when the internal circuit 2 is in idle mode, the current flowing through the internal circuit 2 becomes smaller compared with when the internal circuit 2 is in normal mode. Therefore, in the second embodiment, it is configured that the power consumption of the regulator 10 when the internal circuit 2 is in idle mode is smaller than the power consumption of the same when the internal circuit 2 is in normal mode.

In the second embodiment, the MOS transistors Tr1 and Tr4 are configured so that the current IR3, which is an estimated maximum current when the internal circuit 2 is in idle mode, flows therethrough. Therefore, the MOS transistors Tr1 and Tr4 can be formed to be smaller in size than the MOS transistor Tr9. Further, the differential amplifier 12 can be formed with low-voltage elements as described in the first embodiment. Therefore, the circuit scale of the differential amplifier 12 can also be reduced.

The regulator 10 of the second embodiment can reduce the current flowing through the regulator 10 when the internal circuit 2 is in idle mode.

Additionally, an n-channel MOS transistor (not shown) may also be further provided in the path between the MOS transistor Tr1 and the MOS transistor Tr4. An inverted signal of the control signal IDLE_DIS may be input to the gate of the MOS transistor. As a result, when the internal circuit 2 is in normal mode, no current flows through the MOS transistors Tr1 and Tr4, and the intermediate potential VFGND may be supplied solely by the Zener diode ZD2.

### Third Embodiment

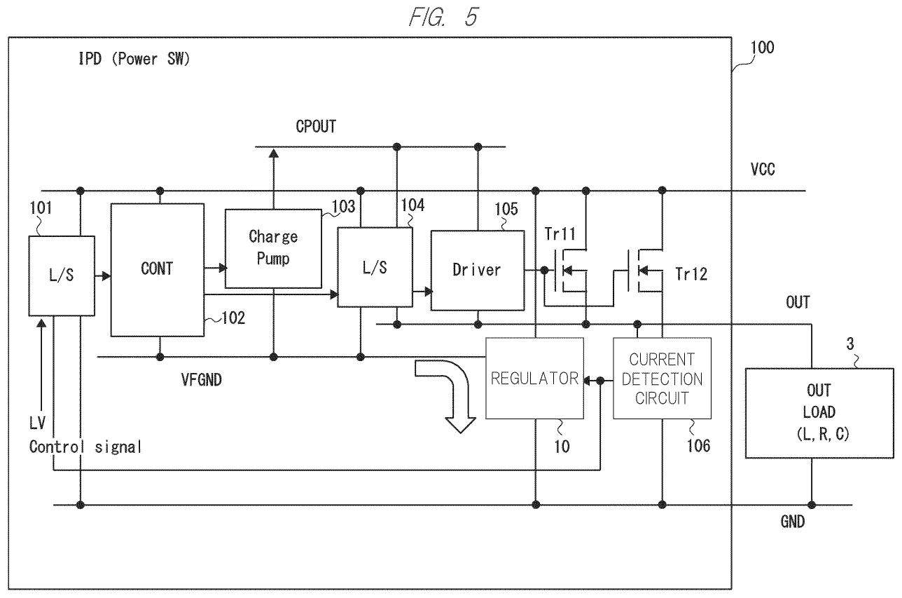

FIG. 5 is a schematic circuit diagram illustrated a configuration of an intelligent power device (IPD) 100 according to a third embodiment. The IPD 100 includes the regulator 10 according to the second embodiment. It should be noted that the IPD 100 may also include the regulator 1 according to the first embodiment.

The IPD 100 includes an n-channel power MOS transistor Tr11, the regulator 1, a level shifter 101, a control circuit 102, a charge pump 103, a level shifter 104, a driver 105, an n-channel sense MOS transistor Tr12, and a current detection circuit 106. The control circuit 102 and the charge pump 103 correspond to the internal circuit 2 described above.

The power MOS transistor Tr11 is provided in the path that supplies the power potential VCC to a load circuit 3, which may include an inductor, a resistor, a capacitor, and the like. The power potential VCC may be generated by a battery. A drive signal from the driver 105 is input to the gate of the power MOS transistor Tr11. The potential at the source of the power MOS transistor Tr11 is output as an output potential OUT.

The regulator 10 has a configuration similar to that of the regulator 10 in the second embodiment and generates the intermediate potential VFGND. The intermediate potential VFGND is supplied to the control circuit 102, the charge pump 103, and the level shifter 104. Also, the regulator 10 receives a detection result from the current detection circuit 106. The regulator 10 can recognize whether the control circuit 102 is set to normal mode or idle mode based on the detection result. That is, the detection result from the current detection circuit 106 corresponds to the control signal IDLE_DIS in the second embodiment. The level shifter 101 converts a control signal that transitions at a predetermined amplitude with the ground potential GND as the Low level into a signal that transitions at a predetermined amplitude with the power potential VCC as the High level. The control circuit 102 controls the charge pump 103 based on the level-shifted control signal and transmits the control signal to the driver 105 via the level shifter 104. The charge pump 103 generates a boost potential CPOUT that is higher than the power potential VCC, in accordance with the control of the control circuit 102. The level shifter 104 converts the control signal from the control circuit 102 into a signal that transitions at a predetermined amplitude with the boost potential CPOUT as the High level. The driver 105 generates a drive signal that drives the gate of the power MOS transistor Tr11 in accordance with the level-shifted control signal. The drive signal is also input to the gate of the sense MOS transistor Tr12. A minute current, which is a copy of the current flowing through the power MOS transistor Tr11 at a low mirror ratio, flows through the sense MOS transistor Tr12. The current flowing through the sense MOS transistor Tr12 is represented as a current Is.

The current detection circuit 106 detects whether the minute current Is flowing through the sense MOS transistor Tr12 is equal to or less than a certain current value. The current detection circuit 106 may, for example, use a comparator to compare the voltage generated in a resistor through which a minute current Is flows with a threshold voltage. Further, the voltage generated across the resistor may be digitized by an analog-to-digital converter (ADC), and the digitized voltage value may be compared with a threshold value.

When the current detection circuit 106 detects that the current Is is below a certain current value, it is determined that the load circuit 3 has entered an idle state. Therefore, the detection result of the current detection circuit 106 is transmitted to the control circuit 102 via the level shifter 101, and the control circuit 102 is set to idle mode. Otherwise, the control circuit 102 is set to normal mode. For example, when the current Is is equal to or lower than a certain current value, the regulator 10 may generate the intermediate potential VFGND using the differential amplifier 12 and the MOS transistor Tr1, and when the current Is is not equal to or lower than a certain current value, the regulator 10 may generate the intermediate potential VFGND using the Zener diode ZD2. Specifically, the detection signal output by the current detection circuit 106 corresponds to the control signal IDLE_DIS in the second embodiment.

In the IPD 100 of the third embodiment, since the intermediate potential VFGND is supplied to the control circuit 102 and the like, the control circuit 102 and the like can be formed with low-voltage elements. Further, when the load circuit 3 is in an idle state, the IPD 100 can reduce the current consumption of the IPD 100 by reducing the current required to generate the intermediate potential VFGND.

In addition, in the third embodiment, the regulator 10 may be replaced with the regulator 1 of the first embodiment. In this case, the intermediate potential VFGND may be generated by the regulator 1 of the first embodiment regardless of the detection result of the current detection circuit 106, that is, regardless of the operating state of the load circuit 3.

In the third embodiment, the regulator 10 may be replaced with a configuration similar to that of the regulator 1 in the first embodiment, and further the current flowing through the regulator 1 may be switched according to the detection result of the current detection circuit 106. For example, the MOS transistors Tr1 and Tr4 may be configured so that the amount of current allowed to flow through the paths of the MOS transistors Tr1 and Tr4 can be switched according to the detection result of the current detection circuit 106. That is, when the control circuit 102 is set to idle mode according to the detection result of the current detection circuit 106, the amount of current flowing through the paths of the MOS transistors Tr1 and Tr4 is made smaller than the current flowing through the paths of the MOS transistors Tr1 and Tr4 when the control circuit 102 is set to normal mode. As a result, when the load circuit 3 is in an idle state, the intermediate potential VFGND may be supplied with lower power consumption. Additionally, to ensure the stable supply of the intermediate potential VFGND, the amount of current supplied to the differential amplifier 12 may be switched according to the detection results from the current detection circuit 106.

In the foregoing, the invention made by the inventors of the present application has been concretely described on the basis of the embodiments. However, it is needless to say that the present invention is not limited to the foregoing embodiments, and various modifications and alterations can be made within the scope of the present invention.

For example, in the regulator according to the above embodiments, the conductivity type (p-type or n-type) of elements such as a semiconductor substrate, a semiconductor layer, and a diffusion layer (diffusion region) may be inverted in the configuration. Therefore, when one of the n-type and p-type conductivity types is designated as a first conductivity type and the other conductivity type is designated as a second conductivity type, the first conductivity type can be p-type and the second conductivity type can be n-type, or conversely, the first conductivity type can be n-type and the second conductivity type can be p-type.

What is claimed is:

1. A regulator comprising:
a reference potential generation circuit that generates a reference potential serving as a reference for a first intermediate potential and a second intermediate potential lower than the first intermediate potential;
a differential amplifier to which the second intermediate potential is supplied as a low potential side power supply and which amplifies a difference voltage between a feedback potential corresponding to the first intermediate potential and the reference potential; and
a first transistor having a gate to which the amplified difference voltage is input, a drain connected to a ground potential via a constant current source or a resistor, and a source that generates the first intermediate potential.

2. The regulator according to claim 1, further comprising:
a second transistor that is controlled to be in an Off state when a circuit to which the first intermediate potential is supplied as a low potential side power supply is in an idle mode; and
a first Zener diode connected in series with the second transistor,
wherein, when the circuit is in a normal mode, the first intermediate potential generated by the first Zener diode is supplied to the circuit.

3. The regulator according to claim 2,
wherein a current flowing through the first transistor is set based on a maximum current of the circuit in the idle mode, and
wherein the current flowing through the second transistor in an On state is set based on the maximum current of the circuit in the normal mode.

4. The regulator according to claim 1,
wherein a diode is provided between the source of the first transistor and a node at which the first intermediate potential is generated.

5. The regulator according to claim 1,
wherein the reference potential generation circuit includes a second Zener diode and a diode connected in series,
wherein an anode of the Zener diode and an anode of the diode are connected to each other,
wherein the reference potential is generated at the anode of the Zener diode, and
wherein the second intermediate potential is generated at a cathode of the diode.

6. A power device comprising:
a reference potential generation circuit that generates a reference potential serving as a reference for a first intermediate potential and a second intermediate potential lower than the first intermediate potential;
a differential amplifier to which the second intermediate potential is supplied as a low potential side power supply and which amplifies a difference voltage between a feedback potential corresponding to the first intermediate potential and the reference potential;
a first transistor having a gate to which the amplified difference voltage is input, a drain connected to a ground potential via a constant current source or a resistor, and a source that generates the first intermediate potential; and
a control circuit to which the first intermediate potential is supplied as a low potential side power supply and that controls a power transistor.

7. A regulator comprising:
a reference potential generation circuit that generates a reference potential that is an intermediate potential between a power supply potential that is an input voltage and a ground potential;
a differential amplifier that uses the power supply potential as a high potential side power supply and amplifies a difference voltage between an output voltage of the regulator and the reference potential; and
a transistor having a gate connected to the output of the differential amplifier, a drain connected to the ground potential via a constant current source or a resistor, and a source serving as the output of the regulator.

8. The regulator according to claim 7,
wherein the transistor is a p-channel MOS transistor.

9. The regulator according to claim 7,
wherein the reference potential is a first reference potential,
wherein the reference potential generation circuit further generates a second reference potential lower than the first reference potential and higher than the ground potential, and
wherein the differential amplifier is supplied with the second reference potential as a low potential side power supply.

10. The regulator according claim 9,
wherein the constant current source is a first constant current source, and
the regulator further comprising a second constant current source connected between a second reference potential output node that outputs the second reference potential of the reference potential generation circuit and the ground potential.

11. The regulator according to claim 7,
wherein the constant current source is a first constant current source, and
the regulator further comprising:
a Zener diode connected between a power supply voltage line to which the power supply potential is supplied and the output of the regulator; and
a switch and a third constant current source connected in series to the output and the ground potential,
wherein the current flowing through the first constant current source or the resistor is smaller than the current flowing through the third constant current source.

12. A power device comprising:
the regulator according to claim 7;
a power transistor provided to supply a power supply potential to a load circuit; and
a control circuit that controls the power transistor,
wherein the control circuit is supplied with the power supply potential and operates using the output voltage of the regulator as a low potential side power supply.

13. The power device according to claim 12, further comprising:
a current detection unit that detects a current flowing through the power transistor,
wherein, in the regulator,
the constant current source is a first constant current source, and
a Zener diode connected between the input voltage and the output, and
a switch and a third constant current source connected in series to the output and a ground potential are included, and
wherein the switch is turned On and Off according to a detection result of the current detection unit.
